(19) United States
(12) Patent Application Publication
(10) Pub. No.: US 2005/0142798 A1
(43) Pub. Date: Jun. 30, 2005

(54) Methods of fabricating semiconductor devices

(76) Inventor: Jin Hyo Jung, Bucheon-city (KR)

Correspondence Address: HANLEY, FLIGHT & ZIMMERMAN, LLC, 20 N. WACKER DRIVE, SUITE 4220, CHICAGO, IL, 60606, US

(21) Appl. No.: 11/023,109

(22) Filed: Dec. 27, 2004

(30) Foreign Application Priority Data
Dec. 26, 2003 (KR) 10-2003-0097920

(51) Int. Cl. H01L 21/76

(52) U.S. Cl. 438/424

(57) ABSTRACT

One example disclosed semiconductor device fabrication method includes depositing a pad oxide layer and a nitride layer on a semiconductor substrate, exposing the semiconductor substrate by patterning the pad oxide layer and the nitride layer so as to define a field region, injecting oxygen ions into the field region, and thermal-treating the ion-injected field region.

### TECHNICAL FIELD

The present disclosure relates to semiconductor devices and processing and, more particularly, to methods of fabricating semiconductor devices.

### BACKGROUND

Recently, as the metal oxide semiconductor (MOS) transistor has become highly integrated, shallow trench isolation (STI) has replaced the traditional local oxidation of silicon structure.

In the conventional STI process, a silicon substrate is etched using a patterned silicon nitride layer as a mask to form a trench or moat. After forming the trench, a dielectric layer is formed on the silicon nitride layer within the trench. The patterned silicon nitride layer is exposed through a chemical mechanical polishing (CMP) process. The patterned silicon is removed to expose the silicon substrate, thereby a field dielectric, i.e., the STI is formed.

In the conventional STI structure, however, the moat is formed between the silicon substrate and STI such that stress and electric field are concentrated at the moat. This concentration of the stress and electric field causes the hump phenomenon, which is irregular current flow to the applied voltage of the MOS transistor.

### BRIEF DESCRIPTION OF THE DRAWINGS

FIG. 1 to FIG. 5 are cross-sectional views illustrating fabrication of the semiconductor device at various stages in the disclosed processes.

### DETAILED DESCRITPION

To clarify multiple layers and regions, the thickness of the layers are enlarged in the drawings. Wherever possible, the same reference numbers will be used throughout the drawing(s) to refer to the same or like parts. When it is said any part such as a layer, film, area, or plate is positioned on another part, it means the part is right on the other part or above the other part with at least one intermediate part. In the mean time, that any part is positioned right on other part means that there is no intermediate part between the two parts.

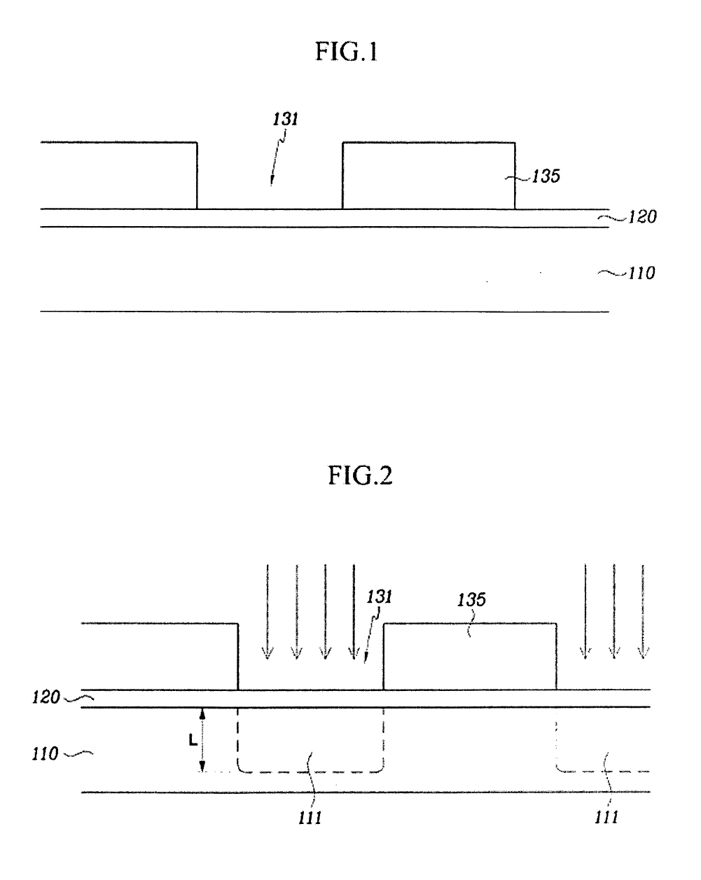

Referring to FIG. 1, a pad oxide layer 120 and a nitride layer 135 are first formed, in sequential order, on a semiconductor substrate 100 at predetermined thicknesses. The nitride layer 135 is preferably deposited at the thickness enough to protect ions from being injected into an active region of the semiconductor substrate in following process. Preferably, the thickness of the nitride layer 135 is in the range of 1000-10000 Å.

Next, the nitride layer 135 is patterned so as to be removed on the field region at which the STI to be formed and remained on the active region at which the MOS transistor to be formed.

Referring to FIG. 2, the oxygen ions are injected into the area 131 at which the nitride layer is removed. In one example, the oxygen ions are injected into the field region 111 of the semiconductor substrate 110 to an extent of solid solubility with an amount in the range of 1×10²⁰-1×10²² [ions/cm^{3].}

Also, according to one example, the oxygen ions are injected at a depth (L) in the range of 1000 Å-5000 Å. The depth of the STI depends on the oxygen ion injection depth such that the energy of the ion injection is determined by the expected depth of the STI.

The exposed field region 111 of the semiconductor substrate 110 can be doped with the oxygen ions through single oxygen ion injection process or multiple injection processes while changing the injection energy to maintain uniform concentration of the doped oxygen ions from the exposed surface of the semiconductor to the depth of the STI to be formed.

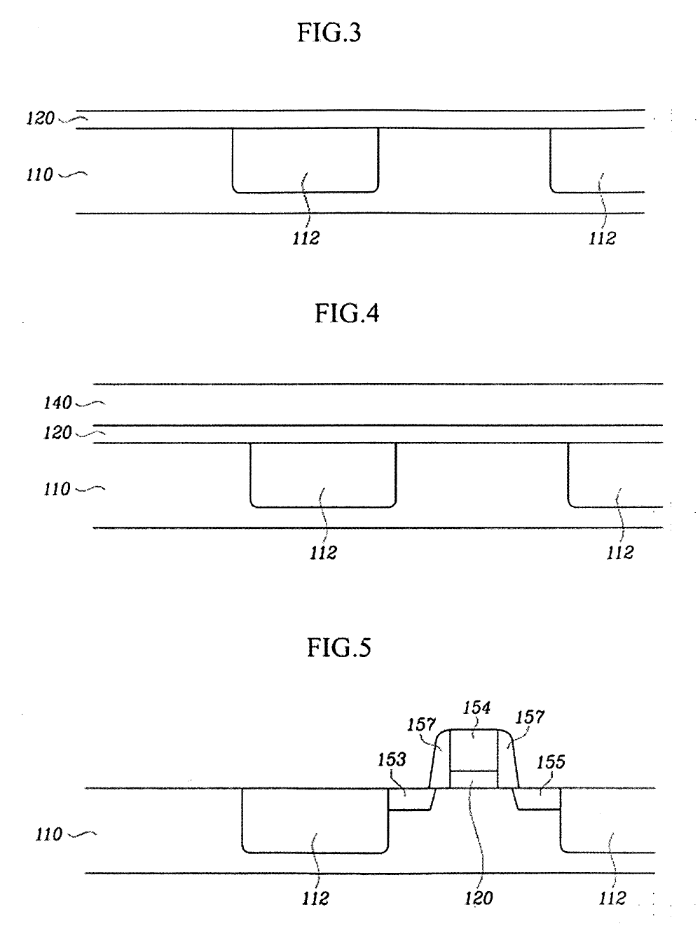

Referring to FIG. 3, the oxygen ions injected to the field region 111 of the semiconductor substrate 110 are activated through a thermal treatment process so as to react with the atoms of the silicon substrate 110, thereby the STI 112 is formed completely. In one example, the thermal treatment is carried out using a rapid thermal annealing equipment or furnace. The remained nitride layer is then removed.

Referring to FIG. 4, sequentially a polycrystalline silicon layer 140 is formed on the pad oxide layer 120 through the CVD process.

Referring to FIG. 5, the poly crystalline silicon layer 140 and the pad oxide layer 120 are patterned through a photolithography process so as to be formed as a gate dielectric 120 and a gate electrode 154. Sequentially, sidewall spacers 157 are formed on sidewalls of the gate electrode 154 and the gate dielectric 129.

Next, low or high concentration impurities are injected into the semiconductor substrate 110 through an ion injection process using an ion injection mask such that a source and drain regions 110 and 155 of the MOS transistor are formed.

In case of forming the STI through the conventional STI process, a trench is formed by etching an STI region of the semiconductor substrate and is filled with the nitride layer, and then the nitride layer is planarized through the CMP process. As disclosed herein, however, the trench and nitride layer formation processes and the CMP process is not required, such that it is possible to simplify the fabrication process and to reduce the whole manufacturing costs and process time.

Also, in the conventional STI process, scratches are likely to occur and nitride residues can be generated, especially in excessive CMP process, resulting in yield loss. In the disclosed STI process, however, the CMP process is not used so as to solve these problems, resulting in improvement of the yield.

Also, filling the trench with the nitride layer in the conventional STI process becomes difficult as the device being highly integrated and is likely to create voids, i.e., empty potions. In the meantime, the STI process disclosed herein skips trench filling process, such that it is possible to form the STI 112 without voids.

Also, the conventional STI process generates depth difference within a single trench along the trench depth due to the characteristic of the dry etch process. However, as disclosed herein, the STI is formed by evenly injecting the oxygen ions into the semiconductor substrate without forming trench such that it is possible to achieve the STI 112 at uniform depth.

Also, in case of the conventional STI process, the CMP process causes grooves on the interface of the sidewalls of the STI and the active region, and the oxide layers of the STI sidewalls are likely to be scooped in the following wet etch process, whereby parasite vertical transistor is created at the grooves formed on the interface of the STI sidewalls and the active regions in the following gate electrode formation process, resulting in the hump phenomenon. However, since the disclosed STI process does not require the CMP process, no grooves occur on the interface of the active region and STI sidewalls. Furthermore, the oxide layer of the STI is close to a thermal oxide layer such that it is not scooped even in the following wet etch process, whereby no parasite vertical transistor is formed, resulting in avoidance of the hump phenomenon.

Additionally, because the oxide layer formed through the oxygen ion injection and thermal treatment in the present STI process is close to the thermal oxide layer, it is possible to improve the device isolation characteristic.

As disclosed above, methods of fabricating a semiconductor device are capable of simplifying STI process and preventing occurrence of the hump phenomenon. To achieve such results, a semiconductor device fabrication method includes depositing a pad oxide layer and a nitride layer on a semiconductor substrate, exposing the semiconductor substrate by patterning the pad oxide layer and the nitride layer so as to define a field region, injecting oxygen ions into the field region, and thermal-treating the ion-injected field region.

In one example, the oxygen ions are injected at a depth in the range of 1000 Å-5000 Å. The nitride layer may be formed at a thickness in the range of 1000 Å-10000 Å. In one arrangement, the oxygen ions are injected with a concentration in the range of 1×10²⁰-1×10²² [ions/cm³].

As described above, in the semiconductor device manufacturing method that is disclosed, the STI is formed through the oxygen ion injection and thermal treatment processes, it is possible to simplify the STI process and improve the device isolation characteristic by avoiding the hump phenomenon.

This patent application makes reference to, incorporates the same herein, and claims all benefits accruing under 35 U.S.C. § 119 from an application for METHOD FOR FABRICATING SEMICONDUCTOR DEVICE filed in the Korean Industrial Property Office on Dec. 26, 2003 and there duly assigned Serial No. 10-2003-0097920.

Although certain apparatus constructed in accordance with the teachings of the invention have been described herein, the scope of coverage of this patent is not limited thereto. On the contrary, this patent covers every apparatus, method and article of manufacture fairly falling within the scope of the appended claims either literally or under the doctrine of equivalents.

1. A method for fabricating a semiconductor device, comprising:
depositing a pad oxide layer and a nitride layer on a semiconductor substrate;
exposing the semiconductor substrate by patterning the pad oxide layer and the nitride layer so as to define a field region;
injecting oxygen ions into the field region; and
thermal-treating the ion-injected field region.

2. The method of claim 1, wherein the oxygen ions are injected at a depth in the range of 1000 Å-5000 Å.

3. The method of claim 1, wherein the nitride layer is formed at a thickness in the range of 1000 Å-10000 Å.

4. The method of claim 1, wherein the oxygen ions are injected with a concentration in the range of 1×10²⁰-1×10²² [ions/cm³].
